(19) United States
(12) Patent Application Publication
(10) Pub. No.: US 2003/0173672 A1
(43) Pub. Date: Sep. 18, 2003

(54) Semiconductor devices and methods for manufacturing the same

(76) Inventor: Tomoyuki Furuhata, Sakata-shi (JP)

Correspondence Address: KONRAD RAYNES VICTOR & MANN, LLP, 315 SOUTH BEVERLY DRIVE, SUITE 210, BEVERLY HILLS, CA, 90212, US

(21) Appl. No.: 10/323,431

(22) Filed: Dec. 18, 2002

(30) Foreign Application Priority Data
Dec. 18, 2001 (JP) 2001-384640

(51) Int. Cl. H01L 23/48

(52) U.S. Cl. 257/758

(57) ABSTRACT

An integrated circuit to which a metal multi-layered wiring technique is applied is structured on a semiconductor substrate 11. There is a metal wiring layer immediately below an interlayer dielectric film 121. A capacitor element C1, which is formed from a specified wiring layer metal 13 on the interlayer dielectric film 121, a capacitor dielectric film 14 in a specified region on the wiring layer metal 13 and a metal pattern 15 thereon, is provided. Further, on the next interlayer dielectric film 122, lead-out electrodes T13 and T15 as parts of the capacitor element C1, which are lead out through vias VIA formed from, for example, W plugs, are formed with a wiring layer metal 16 in an upper layer.

Applicant hereby incorporates by reference Japanese Application No. 2001-384640, filed Dec. 18, 2001, in its entirety.

### TECHNICAL FIELD

The present invention relates to semiconductor devices, including capacitor elements that are provided in the form of thin films within multi-layered wirings that comprise an integrated circuit, and methods for manufacturing the same.

### RELATED ART

In pursuit of electronic equipment that is even smaller, lighter and faster with a higher frequency in recent years, there are demands for a higher integration of semiconductor integrated circuit elements that are mounted on electronic equipment, and passive components such as electric wirings, resistance elements and capacitor elements are advanced toward further miniaturization and higher performance.

FIGS. 7(a) and (b) show cross-sectional views of the structures of conventional capacitor elements that may be provided in semiconductor integrated circuits. Referring to FIG. 7(a), in a capacitor element C5a, a polycrystalline silicon layer 53 is formed on a capacitor dielectric film 52 (for example an oxide film) on a specified high concentration region 51 over a semiconductor substrate 50. The polycrystalline silicon layer 53 extends over an element isolation dielectric film 54 where a lead-out wiring of one of the capacitor electrodes is provided. Also, another lead-out wiring for the other capacitor electrode is provided through a higher concentration section 55 of the specified high concentration region 51.

Referring to FIG. 7(b), in a capacitor element C5b, a first polycrystalline silicon layer 531 is formed on an element isolation dielectric film 54 of a semiconductor substrate 50. A second polycrystalline silicon layer 532 is formed over the polycrystalline silicon layer 531 on a capacitor dielectric film 56 that is formed from stacked layers of, for example, oxide film/nitride film/oxide film. The first and second polycrystalline silicon layers 531 and 532 become capacitor electrodes, respectively.

The structure indicated in FIG. 7(a) is greatly affected by parasitic capacitances, and is highly temperature dependent and voltage dependent, in other words, highly sensitive. Moreover, since it is located in the lowermost layer, it is apt to be affected by upper layer wirings. Accordingly, its accuracy cannot be improved to high levels. Therefore, it is not suitable for forming capacitor elements in which an accuracy in the order of f F units is required due to greater miniaturization.

In the structure indicated in FIG. 7(b), two layers of polycrystalline silicon layers are required for composing a capacitor element, which causes a manufacturing disadvantage, i.e., an increased number of manufacturing steps. Moreover, such a structure has a temperature dependency and a voltage dependency, and is apt to be affected by upper layer wirings.

### SUMMARY

Embodiments relates to a semiconductor device for an integrated circuit to which a metal multi-layer wiring technique is applied, including a capacitor element formed from a capacitor dielectric film formed in a specified region on a specified wiring layer metal on an interlayer dielectric layer and a metal pattern provided on the capacitor dielectric film.

Embodiments also relate to a method for manufacturing a semiconductor device for an integrated circuit to which a metal multi-layer wiring technique is applied, the method including: patterning an n-th (wherein n is a natural number) layer metal for a predetermined wiring layer on an interlayer dielectric film to form a first capacitor electrode together with other wirings; coating a capacitor dielectric film on the first capacitor electrode; forming a second capacitor electrode metal on the capacitor dielectric film; and leaving the second capacitor electrode metal and the capacitor dielectric film in a specified pattern on the first capacitor electrode and removing the same on other areas.

Embodiments also relate to a method for manufacturing a semiconductor device for an integrated circuit to which a metal multi-layer wiring technique is applied, the method including forming a first capacitor electrode metal on an interlayer dielectric film; coating at least a capacitor dielectric film on the first capacitor electrode metal; and patterning an n-th (n is a natural number) layer metal for a predetermined wiring layer to form a second capacitor electrode together with other wirings on the capacitor dielectric film.

Embodiments also relate to a semiconductor device for an integrated circuit to which a metal multi-layer wiring technique is applied, including a capacitor element formed from a capacitor dielectric film formed in a specified region between first and second electrodes, wherein one of the first and second electrodes is formed from a wiring layer metal, and the other of the first and second electrodes is formed from a metal pattern that is not a wiring layer metal.

Embodiments also relate to a method for manufacturing a semiconductor device for an integrated circuit to which a metal multi-layer wiring technique is applied, including: forming a first capacitor electrode on an interlayer dielectric layer; forming a capacitor dielectric layer in the first capacitor electrode; and forming a second capacitor electrode on the dielectric layer; wherein the capacitor electrodes are formed so that one of the first and second capacitor electrodes is formed by patterning a wiring layer and the other of the first and second capacitor electrodes is formed by patterning a layer that is not a wiring layer.

### BRIEF DESCRIPTION OF THE DRAWINGS

Embodiments of the invention are described with reference to the accompanying drawings which, for illustrative purposes, are schematic and not necessarily drawn to scale.

FIG. 1 shows a cross-sectional view of a structure of a capacitor element included in a semiconductor device in accordance with a first illustrated embodiment of the present invention.

FIG. 2 shows a cross-sectional view of a portion of a manufacturing method that realizes the structure of the first illustrated embodiment shown in FIG. 1.

FIG. 3 shows a cross-sectional view of a structure of certain portions in an applied example related to the first illustrated embodiment shown in FIG. 1.

FIG. 4 shows a cross-sectional view of a structure of a capacitor element included in a semiconductor device in accordance with a second illustrated embodiment of the present invention.

FIG. 5 shows a cross-sectional view of a portion of a manufacturing method that realizes the structure of the second illustrated embodiment shown in FIG. 4.

FIG. 6 shows a cross-sectional view of a structure of certain portions in an applied example related to the second illustrated embodiment.

FIGS. 7(a) and (b) show cross-sectional views of the structures of conventional capacitor elements that may be provided in semiconductor integrated circuits.

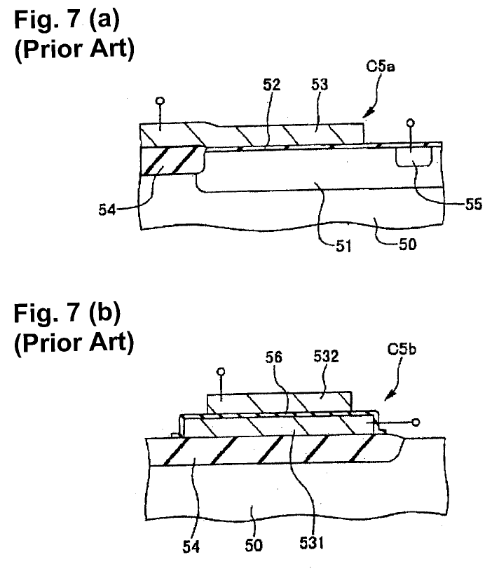

### DETAILED DESCRIPTION

The conventional capacitor element structures described above are apt to be affected by upper layer wirings that handle signals, and such structures make it difficult to provide controlled capacitance values. Also, since they belong to manufacturing steps for lower layers in a multi-layered wiring structure, some undesirable deviations with respect to the design cannot be avoided due to temperature interferences and the like during manufacturing steps for other layers in the multi-layer wiring structure.

Also, when attempting to correct design errors, since the manufacturing steps for the capacitors are conducted in the first half of the entire process as described above, the lead time (time required for consideration of design changes and countermeasures) is long and adjustments are difficult.

Preferred embodiments of the present invention have been made in view of the circumstances described above, and an object of certain embodiments is to provide semiconductor devices having capacitor elements that can provide well controlled capacitor values and shorten the lead time, and methods for manufacturing the same.

A semiconductor device in accordance with a first embodiment of the present invention relates to a semiconductor integrated circuit to which a metal multi-layer wiring technique is applied, and is characterized in comprising a capacitor element formed from a capacitor dielectric film formed in a specified region on a specified wiring layer metal on an interlayer dielectric layer and a metal pattern provided after the specified wiring layer metal.

A semiconductor device in accordance with a second embodiment of the present invention relates to a semiconductor integrated circuit to which a metal multi-layer wiring technique is applied, and is characterized in comprising a capacitor element formed from a specified metal pattern on an interlayer dielectric layer, a capacitor dielectric film formed in a specified region on the metal pattern, and a wiring layer metal formed above.

By the semiconductor devices in accordance with the embodiments described above, a capacitor element that uses metal for both of its electrodes is composed. A capacitor element having a small parasitic capacitance and low temperature and voltage dependency is realized. Since it can be located close to the upper layer wirings, structures that are difficult to be affected by the upper wiring layers and have a short lead time for capacitor correction can be expected.

In the above embodiments, one of the capacitor electrodes uses a wiring layer metal, and the other is provided as a metal pattern for a capacitor electrode. The metal pattern for the capacitor electrode can be structured to have a smaller film thickness than the metal used as a wiring layer. This is because it is not routed around for a long distance like wiring layers and the wiring resistance thereof does not need to be strictly controlled. Also, the thinner, the smaller the step difference and the easier the planarization. For this reason, an embodiment related to the first embodiment above is characterized in that a film thickness of the metal pattern on the capacitor dielectric film is small compared to that of the specified wiring layer metal. Also, an embodiment related to the second embodiment above is characterized in that a film thickness of the wiring layer metal on the capacitor dielectric film is large compared to that of the specified metal pattern.

It is noted that lead-out electrodes of the capacitor element may be connected to the same wiring layer metal in an upper layer through vias, respectively. Also, it is characterized in that the capacitor dielectric film may be a single layer or a stacked layer selected from, for example, an oxide film family and a nitride film family.

A first method embodiment for manufacturing a semiconductor device relates to an integrated circuit to which a metal multi-layer wiring technique is applied, and the method is characterized in comprising the steps of: patterning an n-th (n is a natural number) layer metal for a predetermined wiring layer on an interlayer dielectric film to form a first capacitor electrode together with other wirings; coating a capacitor dielectric film on the first capacitor electrode; forming a second capacitor electrode metal on the capacitor dielectric film; and leaving the second capacitor electrode metal and the capacitor dielectric film in a specified pattern on the first capacitor electrode and removing the same on other areas.

A second method embodiment for manufacturing a semiconductor device in accordance with relates to an integrated circuit to which a metal multi-layer wiring technique is applied, and the method is characterized in comprising the steps of: forming a first capacitor electrode metal on an interlayer dielectric film; coating at least a capacitor dielectric film on the first capacitor electrode metal; and patterning an n-th (n is a natural number) layer metal for a predetermined wiring layer to form a second capacitor electrode together with other wirings on the capacitor dielectric film.

By the semiconductor devices in accordance with the method embodiments described above, a capacitor element that uses metal for its both electrodes is realized. A capacitor element having a small parasitic capacitance and low temperature and voltage dependency is realized. By designing the n-th layer to be located close to upper layer wirings, structures that are less likely to be affected by the upper wiring layers and have a short lead time for capacitor correction can be expected.

An embodiment related to the first method embodiment described above is characterized in further comprising the steps of: forming a next interlayer dielectric film entirely to cover the second capacitor electrode; and patterning a (n+1)-th layer metal for a wiring layer on the interlayer dielectric film to form a lead-out electrode from the first capacitor electrode as a capacitor element and a lead-out electrode from the second capacitor electrode metal through vias, respectively.

Another embodiment related to the first method embodiment described above is characterized in that the layer metal for the wiring layer and the capacitor electrode metal are patterned through a hard mask, and the hard mask is partially removed when at least the capacitor dielectric film or the vias are formed.

An embodiment related to the second method embodiment described above is characterized in further comprising the steps of: forming a next interlayer dielectric film entirely to cover the n-th layer metal for the predetermined wiring layer; and patterning a (n+1)-th layer metal for a wiring layer on the interlayer dielectric film to form a lead-out electrode from the first capacitor electrode as a capacitor element and a lead-out electrode from the second capacitor electrode metal through vias, respectively.

In certain embodiments, the lead-out electrodes can be set to favorably influence the handling and controllability of connections. Also, certain embodiments are provided to improve the processing accuracy in view of the present state where more hard masks (oxide films) are frequently used in metal processings with further miniaturization of wirings. To realize capacitor elements that use metal, hard masks need to be removed at least partially.

Furthermore, the method for manufacturing a semiconductor device according to certain embodiments is characterized in that a planarization process by a chemical mechanical polishing method may preferably conducted for each of at least the interlayer dielectric films. This contributes to an improvement of the processing accuracy and controllability.

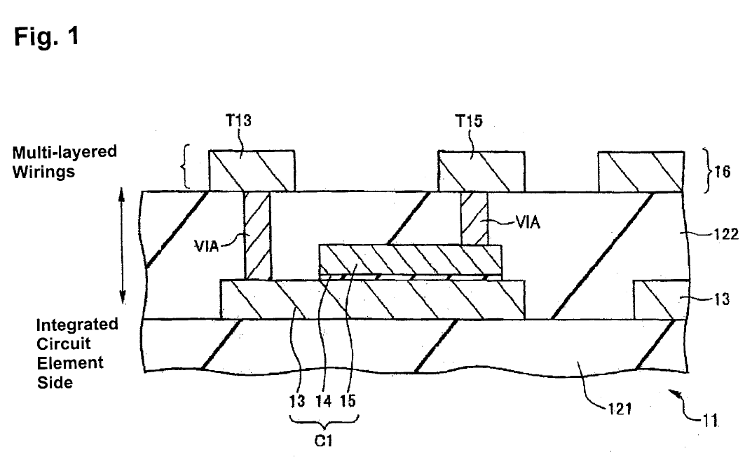

FIG. 1 shows a cross-sectional view of the structure of a capacitor element included in a semiconductor device in accordance with a first illustrated embodiment of the present invention. An integrated circuit (not shown) to which a metal multi-layered wiring technique is applied is structured on a semiconductor substrate 11. There may preferably be a metal wiring layer (not shown) immediately below an interlayer dielectric film 121. A capacitor element C1, which is formed from a specified wiring layer metal 13 on the interlayer dielectric film 121, a capacitor dielectric film 14 in a specified region on the wiring layer metal 13 and a metal pattern 15 thereon, is provided.

Further, on the next interlayer dielectric film 122, lead-out electrodes T13 and T15 as parts of the capacitor element C1, which are led out through vias VIA formed from, for example, W plugs, are formed with a wiring layer metal 16 in an upper layer. Other dielectric films and wiring layers that may be further stacked in layers are omitted in FIG. 1.

In the structure described above, a part of the wiring layer metal 13 that also forms other wiring layers of the integrated circuit composes one capacitor electrode A of the capacitor element C1, and the metal pattern 15 composes another capacitor electrode B of the capacitor element C1. The metal pattern 15 is defined by a metal layer for capacitor electrodes that is provided after the wiring layer metal 13. The film thickness of the metal pattern 15 is smaller than that of the wiring layer metal 13. This is because the metal pattern 15 does not have to be routed around for a long distance like the wiring layer metal 13, and its wiring resistance does not need to be strictly controlled. Also, the thinner, the smaller its step difference, which makes the planarization easier.

Also, the capacitor dielectric film 14 may be composed of a single layer or a stacked layer of dielectric material that is preferably selected from an oxide film family and a nitride film family, such as, a silicon oxide film, a silicon nitride film, a stacked layer of oxide film and nitride film, and the like.

According to the structure of the first illustrated embodiment, the capacitor element C1 can be composed using the metal 13, 15 in both of the electrodes. As a result, a capacitor element having a small parasitic capacitance and low temperature and voltage dependence is realized. Also, since structures in which the wiring layer metal 13 is located close to the upper wiring layer are possible, structures that are less likely to be affected by the upper wiring layer and structures having a short lead time for capacitance corrections can be expected.

Also, the provision of the lead-out electrodes T13 and T15 with the same layer 16 can be favorably reflected on the connection handling and controllability. The interlayer dielectric films 121 and 122 are planarized layers preferably obtained by a chemical mechanical polishing method, which contributes to the improvement of element accuracy.

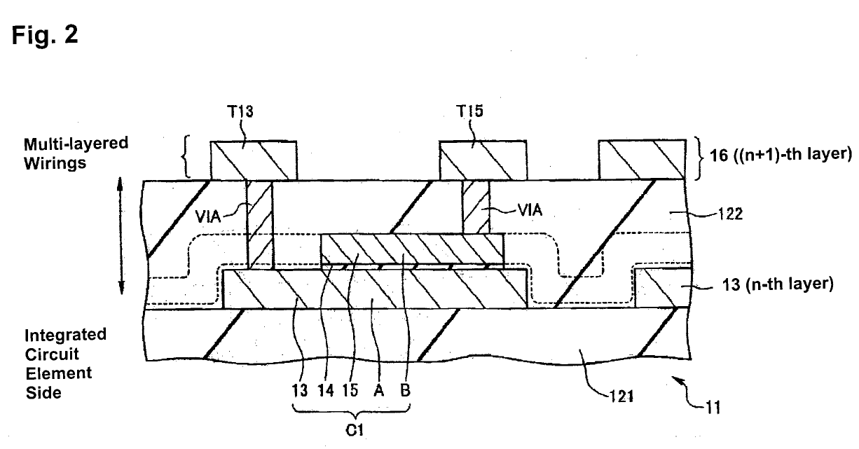

FIG. 2 shows a cross-sectional view of a portion of a manufacturing method embodiment that realizes the structure of the first illustrated embodiment shown in FIG. 1. In the following description, the same reference numbers shall be assigned to components similar to these shown in FIG. 1. This relates to an integrated circuit to which a metal multi-layered wiring technique is applied, provided on a semiconductor substrate 11. An n-th (n is a natural number) layer metal 13 for a predetermined wiring layer is formed on an interlayer dielectric layer 21, and is patterned, using a photolithography technique, to form a first capacitor electrode A together with other wirings.

Next, a capacitor dielectric film 14 is coated on the first capacitor electrode A. The capacitor dielectric film 14 is preferably formed with dielectric material by a CVD method as described above. Further, a second capacitor electrode metal 15 is formed on the capacitor dielectric film 14. As a result, stacked layers including the one shown in a broken line are formed.

Next, using a lithography technique, the second capacitor electrode metal 15 and the capacitor dielectric film 14 are left in a predetermined pattern on the first capacitor electrode A, and removed in other areas indicated by the broken line. By this, a capacitor electrode B having the same pattern as that of the capacitor dielectric film 14 is formed.

Then, the next interlayer dielectric film 122 is formed, which is then preferably planarized by a CMP (chemical mechanical polishing) method. Thereafter, vias are formed in the interlayer dielectric film 122 by using a photolithography technique, and vias VIA are formed with, for example, W plugs. Next, an (n+1)-th layer for a wiring layer 16 is formed. By using a photolithography technique, the wiring layer 16 is patterned to form lead-out electrodes T13 and T15 for the capacitor element C1 together with other wirings. Other dielectric films and wiring layers that may be further stacked in layers are omitted.

By the method described above for forming the first illustrated embodiment, the capacitor element C1 using metal 13, 15 for both of its electrodes is realized. By this, capacitor elements having a small parasitic capacitance and low temperature and voltage dependency can be manufactured. By designs in which the n-th layer is located close to the upper wiring layer, structures that are less likely to be affected by the upper wiring layer and structures that have a short lead time for capacitor correction can be expected.

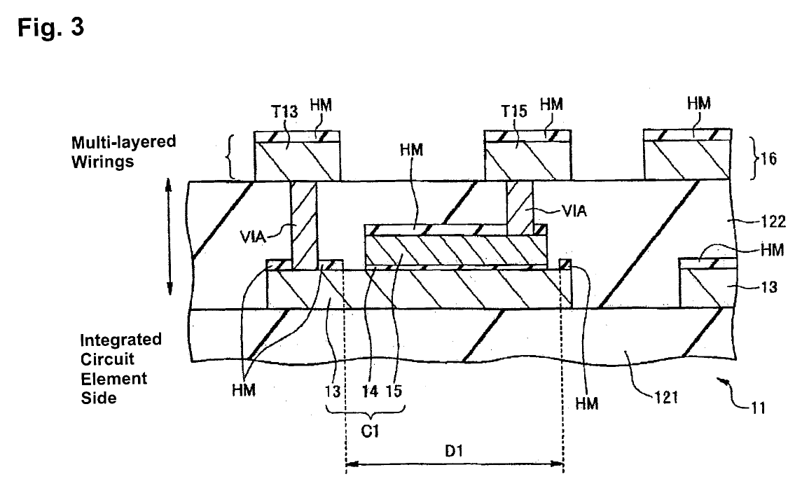

FIG. 3 shows a cross-sectional view of a structure of certain portions in an applied example related to the method for forming the first illustrated embodiment shown in FIG. 1. In the following description, the same reference numbers shall be assigned to components similar to those of the first embodiment. This example is different from the first illustrated embodiment shown in FIG. 1 in that a wiring layer metal 13, a metal pattern 15 and a wiring layer metal 16 including lead-out electrodes T13 and T15 are processed through hard masks (oxide films) HM.

Hard masks (oxide films) HM are frequently used in metal processings with further miniaturization of wirings in an attempt to improve the processing accuracy. To realize capacitor elements that use metal, hard masks HM need to be removed at least partially (i.e., a region D1). More specifically, after patterning the wiring layer metal 13, a hard mask HM in the region D1 and in a region where the capacitor element C1 is formed is selectively removed. Then, a capacitor dielectric film 14 is formed, and a metal pattern 15 formed on the capacitor dielectric film 14 is patterned with a hard mask HM.

Then, an interlayer dielectric film 122 is formed, vias VIA with W plugs are formed, and a wiring layer metal in an upper layer 16 is patterned with a hard mask HM. As a result, lead-out electrodes T13 and T15 as parts of the capacitor element C1 are formed.

By the applied example described above, the capacitor element C1 using metal 13, 15 for both of its electrodes, which has a small parasitic capacitance and low temperature and voltage dependency, is realized. By forming the capacitor element C1 to be located close to an upper wiring layer, structures that are less likely to be affected by the upper wiring layer and structures that have a short lead time for capacitor correction can be expected.

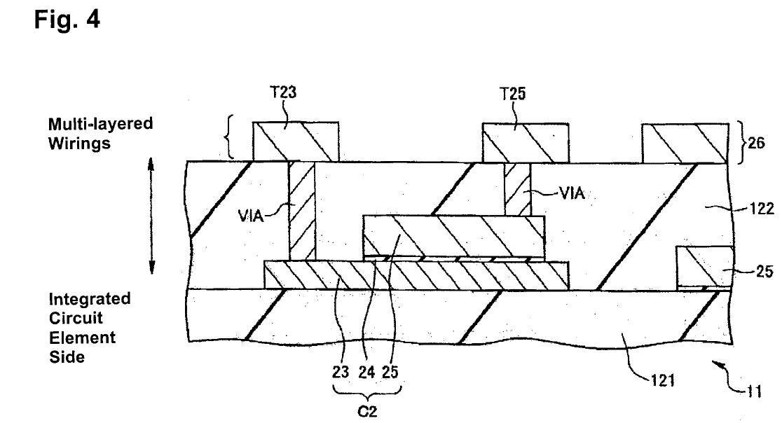

FIG. 4 shows a cross-sectional view of certain structures of a capacitor element included in a semiconductor device in accordance with a second illustrated embodiment of the present invention. In the following description, the same reference numbers shall be assigned to components similar to those of the first illustrated embodiment. An integrated circuit (not shown) to which a metal multi-layered wiring technique is applied is structured on a semiconductor substrate 11. There preferably is a metal wiring layer (not shown) immediately below an interlayer dielectric film 121. A capacitor element C2, which is formed from a specified metal pattern 23 on the interlayer dielectric film 121, a capacitor dielectric film 24 in a specified region on the metal pattern 23 and an upper wiring layer metal 25 thereon, is provided.

Further, on the next interlayer dielectric film 122, lead-out electrodes T23 and T25 as parts of the capacitor element C2, which are lead out through vias VIA formed from, for example, W plugs, are formed with a wiring layer metal 26 in an upper layer. Other dielectric films and wiring layers that may be further stacked in layers are omitted from FIG. 4.

In the structure described above, a part of the metal pattern 23 that is formed for capacitor electrodes comprises one capacitor electrode A of the capacitor element C2, and the wiring layer metal 25 that also forms other wiring layers of the integrated circuit comprises another capacitor electrode B of the capacitor element C2. The film thickness of the wiring layer metal 25 is preferably greater than that of the metal pattern 23. It is advantageous for the wiring layer metal 25 to have a greater film thickness for lower resistance. The metal pattern 23 does not have to be routed around for a long distance like the wiring layer metal 25, and its wiring resistance does not need to be strictly controlled. Also, the thinner, the smaller its step difference, which makes the planarization easier.

Also, the capacitor dielectric film 24 may be composed of a single layer or a stacked layer of dielectric material that is selected from, for example, an oxide film family and a nitride film family, such as, a silicon oxide film, a silicon nitride film, a stacked layer of oxide film and nitride film, and the like.

According to the structure of the second illustrated embodiment, the capacitor element C2 can also be composed using the metal 23, 25 in both of the electrodes. As a result, a capacitor element having a small parasitic capacitance and low temperature and voltage dependence is realized. Also, since structures in which the metal pattern 23 and the wiring layer metal 25 are located close to an upper wiring layer are possible, structures that are less likely to be affected by the upper wiring layer and structures having a short lead time for capacitance corrections can be expected.

Also, the provision of the lead-out electrodes T23 and T25 with the same layer 26 can be favorably reflected on the connection handling and controllability. The interlayer dielectric films 121 and 122 are planarized layers obtained by a chemical mechanical polishing method, like the first embodiment, which contributes to the improvement of element accuracy.

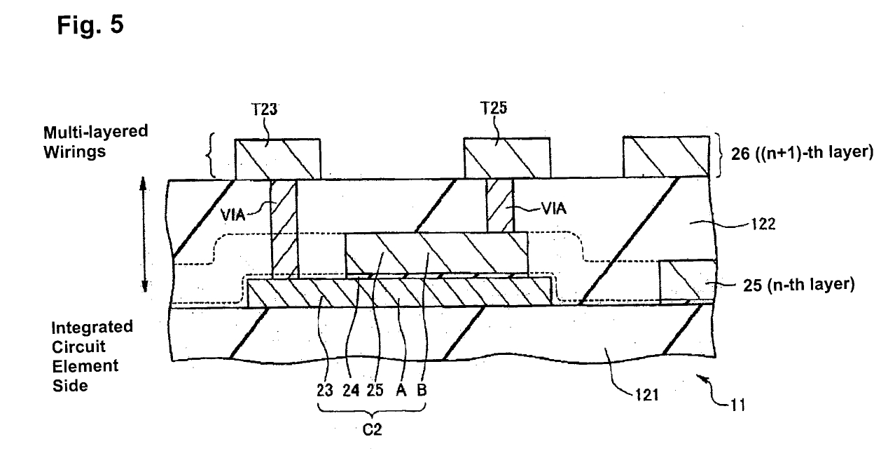

FIG. 5 shows a cross-sectional view of a portion of a manufacturing method that realizes the structure of the second illustrated embodiment shown in FIG. 4. In the following description, the same reference numbers shall be assigned to components similar to these shown in FIG. 4. This relates to an integrated circuit (not shown), to which a metal multi-layered wiring technique is applied, provided on a semiconductor substrate 11. A capacitor electrode metal 23 is formed in a specified region on an interlayer dielectric layer 21, using a photolithography technique, and then patterned to form a first capacitor electrode A.

Next, a capacitor dielectric film 24 is coated on the first capacitor electrode A. The capacitor dielectric film 24 is formed with dielectric material by a CVD method as described above. Further, an n-th (n is a natural number) layer metal 25 for a wiring layer is formed on the capacitor dielectric film 24 (including portions indicated in broken lines).

Next, using a lithography technique, the n-th layer metal 25 for a wiring layer and the capacitor dielectric film 24 are left in a predetermined pattern on the first capacitor electrode A while forming other wiring layers, and removed in other areas indicated by the broken lines. By this, a capacitor electrode B having the same pattern as that of the capacitor dielectric film 24 is formed.

Then, the next interlayer dielectric film 122 is formed, which is then preferably planarized by a CMP (chemical mechanical polishing) method. Thereafter, vias are formed in the interlayer dielectric film 122 by using a photolithography technique, and vias VIA are formed with, for example, W plugs. Next, an (n+1)-th layer for a wiring layer 26 is formed. By using a photolithography technique, the wiring layer 26 is patterned to form lead-out electrodes T23 and T25 for the capacitor element C1 together with other wirings. Other dielectric films and wiring layers that may be further stacked in layers are omitted from FIG. 5.

By the method described above for forming the second illustrated embodiment, the capacitor element C2 using metal 23, 25 for both of its electrodes is realized. By this, capacitor elements having a small parasitic capacitance and low temperature and voltage dependency can be manufactured. By designs in which the n-th layer is located close to an upper wiring layer, structures that are difficult to be affected by the upper wiring layer and structures that have a short lead time for capacitor correction can be expected.

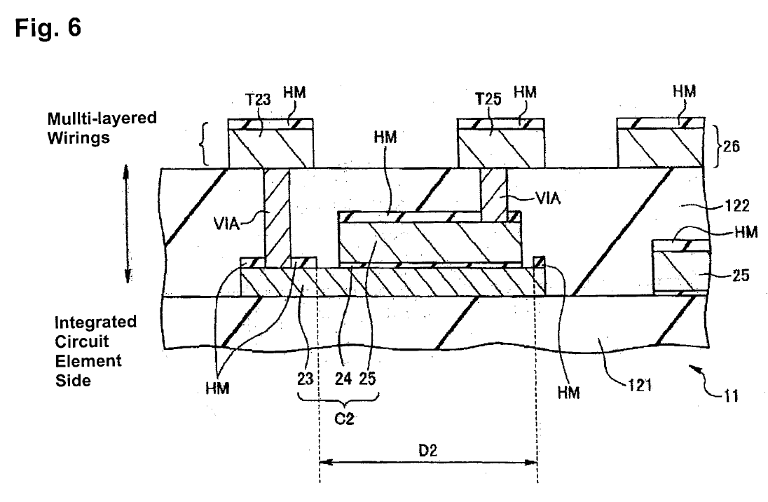

FIG. 6 shows a cross-sectional view of a structure of portions in an applied example related to the method for forming the second illustrated embodiment described above. In the following description, the same reference numbers shall be assigned to components similar to those of the second embodiment. This example is different from the embodiment shown in FIG. 4 in that a metal pattern 23, a wiring layer metal 25 and a wiring layer metal 26 including lead-out electrodes T23 and T25 are processed through hard masks (oxide films) HM.

Halrd masks (oxide films) HM are frequently used in metal processings with further miniaturization of wirings in an attempt to improve the processing accuracy. To realize capacitor elements that use metal, hard masks HM are removed at least partially (i.e., a region D2). More specifically, after patterning the metal pattern 23, a hard mask HM in the region D2 and in a region where the capacitor element C2 is formed is selectively removed. Then, a capacitor dielectric film 24 is formed, and a wiring layer metal 25 formed on the capacitor dielectric film 24 is patterned with a hard mask HM.

Then, an interlayer dielectric film 122 is formed, vias VIA with W plugs are formed, and a wiring layer metal 26 in an upper layer is patterned with a hard mask HM. As a result, lead-out electrodes T23 and T25 as parts of the capacitor element C2 are formed.

By the applied example related to the method for forming the second embodiment described above, the capacitor element C2 using metal 23, 25 for both of its electrodes, which has a small parasitic capacitance and low temperature and voltage dependency, is realized. By forming the capacitor element C2 to be located close to an upper wiring layer, structures that are less likely to be affected by the upper wiring layer and structures that have a short lead time for capacitor correction can be expected.

Embodiments described above may provide a design that can avoid influences of upper layer wirings that handle signals as much as possible, and give a well controlled capacitance value with metal electrodes. Also, it is expected that deviations with respect to the design due to temperature interferences and the like can be suppressed to a range that can be readily corrected. In other words, when design errors are to be corrected, a long lead time can be secured and adjustments can be readily made if steps of manufacturing capacitors are conducted near the end of the entire process.

It is noted that, among the capacitor elements C1 and C2, the metal patterns 15, 23, which may not be restricted by the integrated circuits, can use metal different from the ordinary wiring layers. Also, many other variations of the capacitor dielectric films 14, 24 are possible, and material having ferromagnetic characteristics may also be used.

By certain embodiments of the present invention as described above, a capacitor element that uses metal for both of its electrodes is composed. By this, a capacitor element having a small parasitic capacitance and low temperature and voltage dependency is realized. Since a design in which a wiring layer metal can be located close to an upper layer wiring are possible, highly accurate structures that are difficult to be affected by the upper wiring layer and structures that are easy to correct capacitors can be expected. As a result, semiconductor devices having capacitor elements which provide well controlled capacitance values and have a short lead time and methods for manufacturing the same can be provided.

In addition, it will be understood that a variety of modifications may be made to the embodiments described above within the scope of the present invention.

What is claimed:

1. A semiconductor device for an integrated circuit to which a metal multi-layer wiring technique is applied, comprising a capacitor element formed from a capacitor dielectric film formed in a specified region on a specified wiring layer metal on an interlayer dielectric layer, and a metal pattern provided on the capacitor dielectric film.

2. A semiconductor device according to claim 1, wherein a film thickness of the metal pattern on the capacitor dielectric film is smaller than that of the specified wiring layer metal.

3. A semiconductor device for an integrated circuit to which a metal multi-layer wiring technique is applied, comprising a capacitor element formed from a specified metal pattern on an interlayer dielectric layer, a capacitor dielectric film formed in a specified region on the metal pattern, and a wiring layer metal formed on the capacitor dielectric film.

4. A semiconductor device according to claim 3, wherein a film thickness of the wiring layer metal on the capacitor dielectric film is larger than that of the specified metal pattern.

5. A semiconductor device according to claim 1, wherein lead-out electrodes of the capacitor element are connected to wirings formed at the same wiring level in an upper layer through vias, respectively.

6. A semiconductor device according to claim 3, wherein lead-out electrodes of the capacitor element are connected to wirings formed at the same wiring level in an upper layer through vias, respectively.

7. A semiconductor device according to claim 1, wherein the capacitor dielectric film is selected from the group of a single layer or a stacked layer selected from an oxide film family and a nitride film family.

8. A semiconductor device according to claim 3, wherein the capacitor dielectric film is selected from the group of a single layer or a stacked layer selected from an oxide film family and a nitride film family.

9. A method for manufacturing a semiconductor device for an integrated circuit to which a metal multi-layer wiring technique is applied, the method comprising:
patterning an n-th (wherein n is a natural number) layer metal for a predetermined wiring layer on an interlayer dielectric film to form a first capacitor electrode together with other wirings;
coating a capacitor dielectric film on the first capacitor electrode;
forming a second capacitor electrode metal on the capacitor dielectric film; and
leaving the second capacitor electrode metal and the capacitor dielectric film in a specified pattern on the first capacitor electrode and removing the same on other areas.

10. A method for manufacturing a semiconductor device according to claim 9, further comprising the steps of:
forming a next interlayer dielectric film entirely to cover the second capacitor electrode; and
patterning a (n+1)-th layer metal for a wiring layer on the next interlayer dielectric film to form a lead-out electrode from the first capacitor electrode as a capacitor element and a lead-out electrode from the second capacitor electrode metal through vias in the next interlayer dielectric film, respectively.

11. A method for manufacturing a semiconductor device according to claim 9, wherein the n-th layer metal for the wiring layer and the capacitor electrode metal are patterned through a hard mask, and the hard mask is partially removed when at least one of the capacitor dielectric film or the vias are formed.

12. A method for manufacturing a semiconductor device according to claim 10, wherein the n-th layer metal for the wiring layer and the capacitor electrode metal are patterned through a hard mask, and the hard mask is partially removed when at least one of the capacitor dielectric film or the vias are formed.

13. A method for manufacturing a semiconductor device for an integrated circuit to which a metal multi-layer wiring technique is applied, the method comprising:
forming a first capacitor electrode metal on an interlayer dielectric film;
coating at least a capacitor dielectric film on the first capacitor electrode metal; and
patterning an n-th (n is a natural number) layer metal for a predetermined wiring layer to form a second capacitor electrode together with other wirings on the capacitor dielectric film.

14. A method for manufacturing a semiconductor device according to claim 13, further comprising the steps of:
forming a next interlayer dielectric film entirely to cover the n-th layer metal for the predetermined wiring layer; and
patterning a (n+1)-th layer metal for a wiring layer on the interlayer dielectric film to form a lead-out electrode from the first capacitor electrode as a capacitor element and a lead-out electrode from the second capacitor electrode metal through vias, respectively.

15. A method for manufacturing a semiconductor device according to claim 13, wherein the capacitor electrode metal and the n-th layer metal for the wiring layer are each patterned while using a hard mask, and the hard mask is partially removed when the capacitor dielectric film and when the vias are formed.

16. A method for manufacturing a semiconductor device according to claim 14, wherein the capacitor electrode metal and the n-th layer metal for the wiring layer are each patterned while using a hard mask, and the hard mask is partially removed when the capacitor dielectric film and when the vias are formed.

17. A method for manufacturing a semiconductor device according to claim 7, wherein a planarization process by a chemical mechanical polishing method is conducted for each of the interlayer dielectric films.

18. A method for manufacturing a semiconductor device according to claim 9, wherein a planarization process by a chemical mechanical polishing method is conducted for each of the interlayer dielectric films.

19. A method for manufacturing a semiconductor device according to claim 13, wherein a planarization process by a chemical mechanical polishing method is conducted for each of the interlayer dielectric films.

20. A semiconductor device for an integrated circuit to which a metal multi-layer wiring technique is applied, comprising a capacitor element formed from a capacitor dielectric film formed in a specified region between first and second electrodes, wherein one of the first and second electrodes is formed from a wiring layer metal, and the other of the first and second electrodes is formed from a metal pattern that is not a wiring layer metal.

21. A method for manufacturing a semiconductor device for an integrated circuit to which a metal multi-layer wiring technique is applied, comprising
forming a first capacitor electrode on an interlayer dielectric layer;
forming a capacitor dielectric layer in the first capacitor electrode; and
forming a second capacitor electrode on the dielectric layer;
wherein the capacitor electrodes are formed so that one of the first and second capacitor electrodes is formed by patterning a wiring layer and the other of the first and second capacitor electrodes is formed by patterning a layer that is not a wiring layer.
